(19) United States
(12) Patent Application Publication
(10) Pub. No.: US 2006/0284631 A1
(43) Pub. Date: Dec. 21, 2006

(54) Imaging test socket, system, and method of testing an image sensor device

(76) Inventor: Steven L. Hamren, Boise, ID (US)

Correspondence Address: TRASK BRITT, P.C., P.O. BOX 2550, SALT LAKE CITY, UT, 84110, US

(21) Appl. No.: 11/140,720

(22) Filed: May 31, 2005

(51) Int. Cl. G01R 31/02

(52) U.S. Cl. 324/761

(57) ABSTRACT

A test socket, a test system and methods of testing an image sensor or other optically interactive device. The test system may include a light source for illuminating the image sensor device. A diffuser may be provided to scatter the light. A test socket may include an area configured for receiving the image sensor device. The image sensor device may be in electrical communication with a printed circuit board. The diffuser may be positioned within the test socket or affixed to the printed circuit board. Optionally, the diffuser may provide support for the image sensor device, or a seat of at least partially optically clear material may provide support for the image sensor device. In another embodiment, a test socket includes a seat of at least partially optically clear material enabling collimated light or diffused light to reach the image sensor device.

### BACKGROUND OF THE INVENTION

1. Field of the Invention

The present invention relates to test sockets for optically interactive devices such as image sensor devices in general and, more particularly, to test sockets having a built-in diffuser. Test sockets having an at least partially optically clear support for the image sensor device and methods of testing the image sensor device are also included.

2. Background of Related Art

Semiconductor devices are routinely subjected to testing for compliance with certain performance requirements, particularly image sensor devices. Optically interactive electronic devices, for example, charge coupled device (CCD) image sensors or complementary metal-oxide semiconductor (CMOS) image sensors, are typically packaged within a housing for subsequent connection to higher-level packaging such as a larger circuit assembly in the form of a carrier substrate. The housing provides electrical interconnection to the larger circuit assembly, provides protection from the surrounding environment and allows light or other forms of radiation to pass through to sensing circuitry located on the image sensor device. A window or transparent lid of the housing typically allows the light to pass through. The image sensor device may include an array of pixels for capturing a light pattern, or image, to be converted into an electric charge pattern. The image sensor device may be tested for the performance of the individual pixels.

Test sockets may be used to facilitate the testing of image sensor devices. FIG. 1A depicts a conventional board socket, or contactor 100 and an image sensor device 110 to be mounted thereon. The contactor 100 may be attached to a carrier substrate, such as a printed circuited board 120. The contactor 100 and the printed circuited board 120 are conventionally in electrical communication with one another, for example, using conductive pathways 165. The image sensor device 110 may be positioned within a cavity 107 in the contactor 100 using a handler socket 140. Electrical communication between the image sensor device 110 and the contactor 100 may be established with conductive channels 160 of the handler socket 140. The contactor 100 includes an opening 105 extending therethrough, from a surface 1.02 in contact with the printed circuit board 120 to the floor 108 of the cavity 107.

Light from a light source 155 may be directed through the printed circuit board 120 and the opening 105 of the contactor 100 at the image sensor device 110 during a test of the image sensor device 110. The printed circuit board 120 may include a passageway 126 for the light, in the form of either an opening therethrough or a window. The light source typically either produces collimated light, or the light is passed through a condenser (not shown) to collimate the light. Collimating the light ensures that most of the light is directed toward the image sensor device, and is not scattered. However, during a test, because all of the light is incident on the image sensor device at the same angle, dirt or imperfections on the window of the housing may result in an incorrect determination of a bad pixel within the image sensor device.

A close-up view of the image sensor device 110 mounted on the contactor 100 is shown in FIG. 1B. The image sensor device 110 is supported by the floor 108 of the cavity 107 in the contactor 100. The outside edges 118 of the window 117 extend over, and are supported by, the floor 108 of the cavity. However, as shown in FIG. 1C, a second image sensor device 110A includes a window 117A that is smaller than the window 117, and does not extend over the floor 108 of the cavity 107. The window 117A of the second image sensor device therefore is not supported by the floor 108 of the cavity 107. This can create stress on the housing of the image sensor device 110. Image sensor devices conventionally are getting smaller, and the windows of the image sensor devices are getting smaller. Therefore, custom supports may be required for image sensor devices of different sizes. These may only be provided at considerable expense.

Accordingly, the inventor has recognized the need for a test socket which will reduce the incidence of false failures during testing of image sensor devices. A test socket providing uniform support for an image sensor device would also be useful.

### BRIEF SUMMARY OF THE INVENTION

The present invention, in a number of exemplary embodiments, includes a test socket, methods of testing an image sensor device, and a system for testing an image sensor device. While the following exemplary test sockets are depicted in terms of testing image sensor devices, it should be understood that the test sockets and testing methods presented herein would work equally well for testing other types of optically interactive electronic devices. The term “optically interactive” as used herein is meant to encompass devices sensitive to various wavelengths of light or other forms of radiation, including, but not limited to, CCD and CMOS image sensors, EPROMs, and photodiodes. The term image sensor device and optically interactive electronic device are used interchangeably herein.

In a first embodiment according to the present invention, a socket for testing an image sensor device includes a device area for removably mounting the image sensor device, an optic port therethrough enabling light to reach the device area, and a diffuser positioned proximate to the device area. A contactor configured for mounting a plurality of image sensor devices is within the scope of the present invention. Separate diffusers associated with each of the plurality of image sensor devices may be provided, or a single diffuser configured to diffuse the light incident on the plurality of image sensor devices may be provided. The contactor may include a seat for supporting the image sensor device. The seat may comprise an opaque material and include optical access to an array of pixels of the image sensor device, or may comprise an at least partially optically clear material. A contactor including a diffuser configured to provide support for the image sensor device is within the scope of the present invention.

In accordance with one aspect of the present invention, a method of testing an image sensor device includes emitting light toward the image sensor device, diffusing the light, receiving the light with the image sensor device, registering an electrical image of the light, and communicating the electrical image to a processing device for evaluation of the image sensor device. The evaluation of the image sensor device may be conveyed externally. A plurality of image sensor devices may be tested simultaneously. The light emitted toward the plurality of image sensor devices may be diffused by a single, contiguous diffuser, or by a like plurality of discrete diffusers. Support may be provided for the image sensor device during testing, by a seat comprising an opaque material including optical access to an array of pixels of the image sensor device, or by a seat comprising an at least partially optically clear material. Support for the image sensor device may be provided by the diffuser.

In accordance with another aspect of the present invention, a system for testing an image sensor device includes a carrier substrate, a test socket operatively connected to the carrier substrate and configured to removably receive the image sensor device, and a diffuser for diffusing light incident on the image sensor device. The diffuser may be located proximate to the carrier substrate or located within the test socket. The test socket may include a seat for supporting the image sensor device. The seat may comprise an opaque material and include optical access to an array of pixels of the image sensor device, or may comprise an at least partially optically clear material. A system with a test socket including a diffuser configured to provide support for the image sensor device is within the scope of the present invention.

Another embodiment of a method of testing an image sensor device includes providing a seat comprising an at least partially optically clear material and having a support surface and a back surface, supporting an image sensor device on the seat, the image sensor device including a window having a surface contiguous with the support surface of the seat, emitting light toward the seat and the image sensor device, receiving the emitted light with the image sensor device, recording an electrical image of the emitted light with the image sensor device, and communicating the electrical image to a processing device for evaluation of the image sensor device.

Another embodiment of a socket for testing an image sensor device includes a device area for removably mounting the image sensor device, an optic port therethrough enabling light to reach the device area, and a seat positioned in the optic port comprising an at least partially optically clear material and having a support surface configured to abut an image sensor device.

Other and further features and advantages of the present invention will be apparent from the following descriptions of the various embodiments when read in conjunction with the accompanying drawings. It will be understood by one of ordinary skill in the art that the following embodiments are provided for illustrative and exemplary purposes only, and that numerous combinations of the elements of the various embodiments of the present invention are possible.

### BRIEF DESCRIPTION OF THE DRAWINGS

FIG. 1A is a conventional system for testing an image sensor device;

FIG. 1B is a conventional contactor and an image sensor device;

FIG. 1C is the conventional contactor of FIG. 1B with another image sensor device;

FIG. 2A is a cross-section of a system of the present invention for testing an image sensor device;

FIG. 2B is a cross-section of another system of the present invention for testing an image sensor device including a first embodiment of a contactor of the present invention;

FIG. 3 is a top view of a second embodiment of a contactor of the present invention;

FIGS. 4A and 4B are views of a third embodiment of a contactor of the present invention;

FIGS. 5A and 5B are views of a fourth embodiment of a contactor of the present invention; and

FIG. 6 is a cross-section of a fifth embodiment of a contactor of the present invention.

### DETAILED DESCRIPTION OF THE INVENTION

Referring in general to the accompanying drawings, various aspects of the present invention are illustrated to show exemplary test sockets, or contactors as well as methods of testing image sensor devices. Common elements of the illustrated embodiments are designated with like reference numerals for clarity. It should be understood that the figures presented are not meant to be illustrative of actual views of any particular portion of a particular test socket, but are merely idealized schematic representations which are employed to more clearly and fully depict the invention. It should further be understood that while depicted in terms of test sockets for image sensors, the test sockets and methods of testing presented herein would work equally well for other types of optically interactive electronic devices as described above.

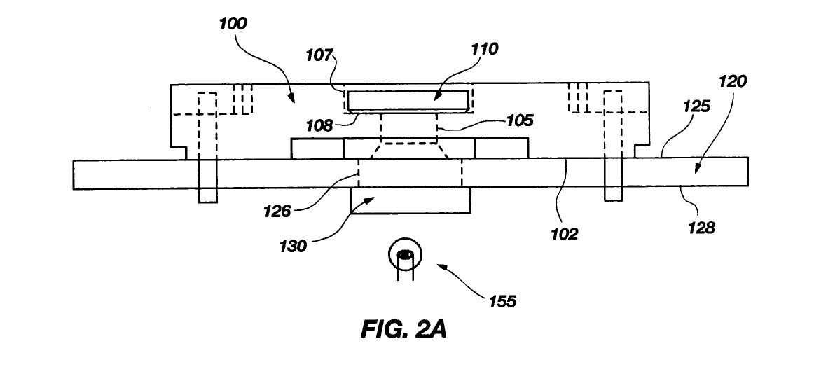

FIG. 2A depicts a board socket, or contactor 100 with an image sensor device 110 mounted thereon. The contactor 100 may be attached to a first side 125 of a carrier substrate, such as a printed circuited board (PCB) 120. The contactor 100 and the printed circuited board 120 are conventionally in electrical communication with one another. The image sensor device 110 is positioned within a cavity 107 in the image sensor device 110, and is supported by the floor 108 of the cavity 107. Electrical communication between the image sensor device 110 and the contactor 100 may be established with a cover 217 (see FIG. 2B), also known as a handler socket. The contactor 100 includes an optic port in the form of an opening 105 extending therethrough, from a surface 102 in contact with the first side 125 of the PCB 120 to the floor 108 of the cavity 107.

Light from a light source 155 may be directed through the PCB 120 and the opening 105 of the contactor 100 at the image sensor device 110 during a test of the image sensor device 110. The PCB 120 may include a passageway 126 for the light, in the form of either an opening therethrough or a window. The light source 155 typically either produces collimated light, or the light is passed through a condenser (not shown) to collimate the light. Collimating, the light ensures that most of the light is directed toward the image sensor device 110, and is not scattered.

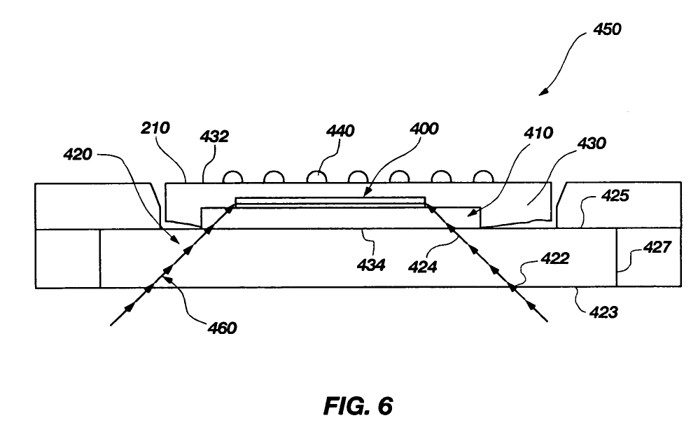

A diffuser 130 may be affixed to a second, opposing side 128 of the printed circuit board 120, for example with an adhesive disposed about or proximate a periphery of the diffuser 130. The diffuser may comprise, for example, finely etched glass or silica substrate. Ground glass, opal glass, and holographic diffusers formed of polycarbonate are additionally within the scope of the present invention. A suitable diffuser material is available from Edmund Optics of Barrington, N.J. The diffuser 130 may scatter the light, causing the light to strike the image sensor device from various angles. The light will pass through a window, or transparent lid 410 (see FIG. 6) of the image sensor device 110 from a variety of different angles; therefore, imperfections on the window will not create distinct dark spots on the array of pixels. The detection of false failures of the pixels may thus be reduced.

During one exemplary method of testing the image sensor device 110, a light source 155 may be provided. The light from the light source 155 may pass through a diffuser 130, and the diffused light may be selectively impinged upon an array of pixels 400 (see FIG. 6) of the image sensor device 110. The image sensor device 110 may register the impinged light and produce an electrical output related to the registered light. The electrical output of the image sensor device may be monitored, for example via the electrical connections, the cover 217, and the PCB 120 to verify that the image sensor device is generating the proper signals in response to the supplied light.

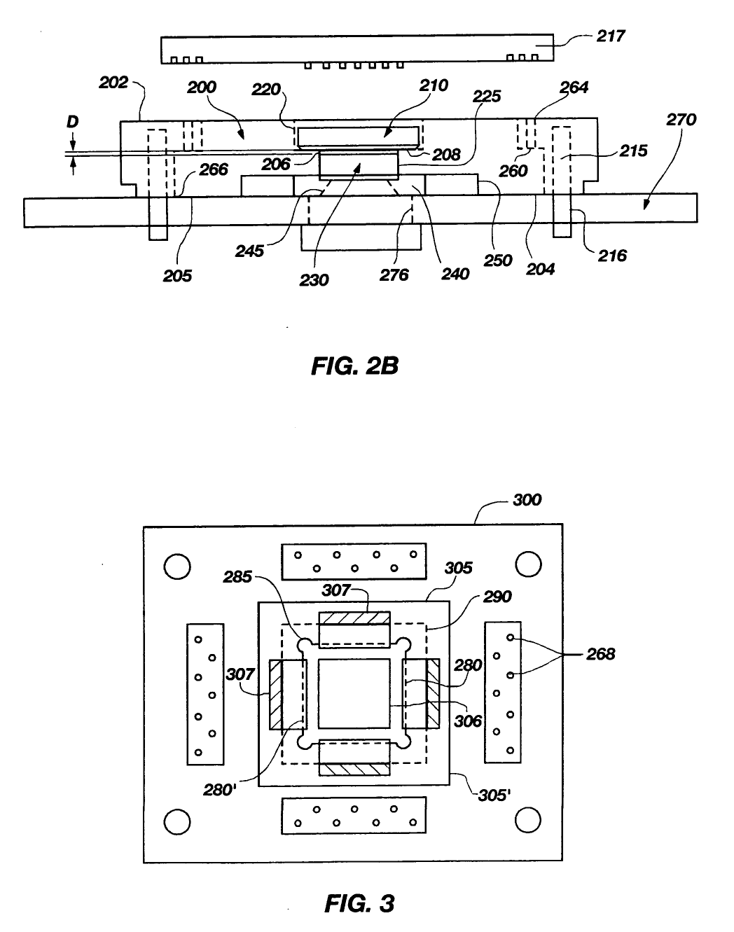

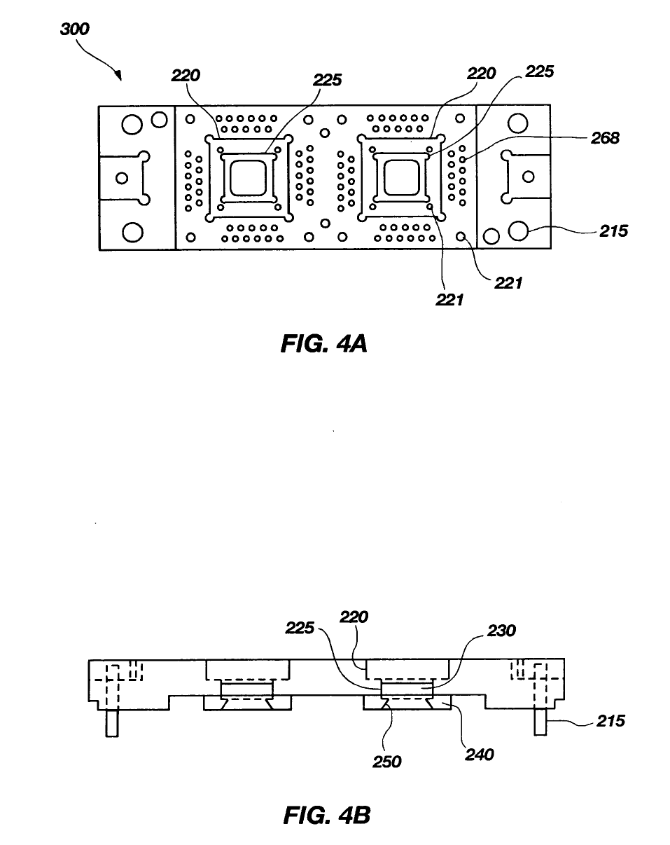

Another exemplary embodiment of a test socket, or contactor 200 according to the present invention is depicted in FIG. 2B. The body 205 of the contactor 200 includes a device cavity 220 in a first surface 202 for an image sensor device 210 to be tested. The image sensor device 210 may be removably mounted in the device cavity 220 during testing thereof. The body 205 may be machined from an insulating material, for example a polyamide-imide such as Torlon 5530. The contactor 200 may include conductive pathways 260. On the first surface 202, a first end 264 of the conductive pathways 260 may be configured for electrical connection to a cover 217 to establish electrical communication between the contactor 200 and the image sensor device 210. Other suitable methods of establishing electrical communication between the contactor 200 and the image sensor device 210 are within the scope of the present invention. The first end 264 of the conductive pathways 260 may comprise external connection points, for example, pins 268 (see FIGS. 3 and 4A). On a second surface 204 of the contactor 200, depicted proximate a PCB 270, a second end 266 of the conductive pathways 260 may be configured for external electrical connection, for example a carrier substrate such as the PCB 270. Pins 215 may be provided on the periphery of the contactor 200 to be received within apertures 216 of the PCB 270, aligning the contactor 200 and the PCB 270.

The image sensor device 210 may be supported by the floor 208 of the device cavity 220. A seat 206 may provide additional support, covering an opening 225 through the contactor 200. The opening 225 may provide an optical port through the contactor 200, and may be configured to house a diffuser 230. The diff-user 230 may thus be positioned proximate to the image sensor device 210, and scatter light incident thereupon, such that the light strikes the image sensor device from a variety of angles. The distance D between the diffuser and the window of the image device 210 is the thickness of the seat 206. The distance D may be in the range from about 0.1 to about 1.0 millimeters, preferably about 0.4 millimeters. A seat 206 having a thickness of 0.4 millimeters may provide the needed support for the image sensor device 210 while enabling a majority of the scattered light from the diffuser 230 to reach the image sensor device 210. The farther the diffuser 230 is positioned from the image sensor device 210, the more of the scattered light will fail to reach the image sensor device 210.

The second surface 204 of the contactor body 205 may include a centrally located hollow 250. A retaining component 240 may attach to the contactor body 205, holding the diffuser 230 in place against the seat 206. The retaining component 240 may include an aperture 245 therethrough, enabling light to pass through the retaining component 240 to the diffuser 230 and the image sensor device 210. The retaining component 240 may be attached to the contactor body 205 with a retaining element, for example a pin or a screw, or with a suitable adhesive material, for example an epoxy, a silicone, an acrylic or other liquid-type adhesive, or a double-sided adhesive-coated tape segment or film, such as a polyimide.

The contactor 200 may be used to test the image sensor device 210. The image sensor device 210 may be placed within the device cavity 220 of the contactor, and removably electrically coupled to the contactor 200, for example, using a cover 217 (see FIG. 2B), which may additionally secure the image sensor device 210 within the device cavity 220. The contactor 200 may be placed in electrical communication with the PCB 270. A light source may be provided, and direct light through a passageway 276 of the PCB 270 and through the aperture 245 in the retaining component 240. The light may be scattered by the diff-user 230, and the image sensor device 210 may register the image received. The registered image may then be communicated to the PCB 270, for example, via the cover 217 and the conductive pathways 260. The image sensor device 210 may be evaluated based on the registered image.

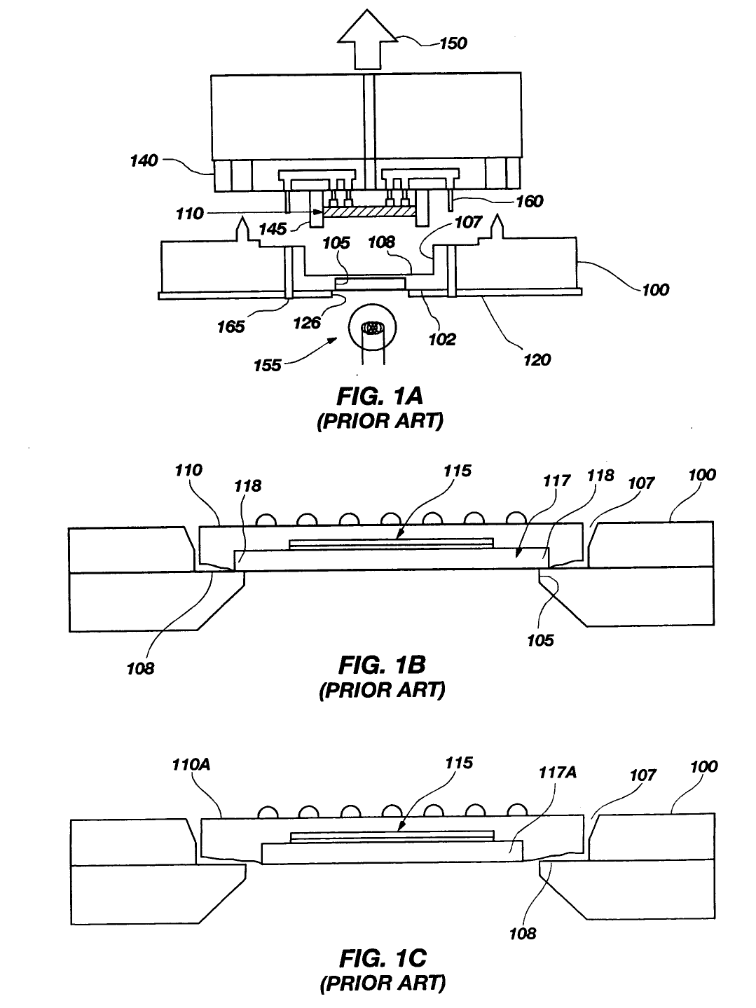

Optionally, a conventional socket may be modified to include a diffuser. Referring back to FIG. 1A, the opening 105 may be sized to accommodate a diffuser. The distance from the light source to the image sensor device is not altered, therefore the focal point of the light source will remain on the image sensor device.

FIG. 3 illustrates a top view of another contactor 300 according to the present invention. A seat 305 of the contactor is configured to support an image sensor device (not shown) during testing. The contactor 300 includes a diffuser 290. The diffuser 290, positioned below the seat 305, may be viewed in FIG. 3 through a central aperture 306 in the seat, and four alignment apertures 307, positioned about the central aperture 306. The central aperture 306 may enable light to pass from the diffuser 290 to the image sensor device during testing. The optional alignment apertures 307 enable a cover, or handler socket 140 (see FIG. 1A) to be properly aligned when placed over the contactor 300. Alignment protrusions 145 (see FIG. 1A) of the handler socket 140 may couple with the alignment apertures 307 of the seat 305. The handler socket 140 may be used to place an image sensor device on the seat 305. The handler socket 140 may additionally provide electrical communication between the image sensor device and the contactor 300. Pins 268 may be provided as external connection points to establish electrical communication between the contactor 300 and the handler socket 140. The handler socket 140 may be removably coupled with the contactor 300, enabling the image sensor device to be inserted or removed, before and after testing.

The seat 305 includes a device cavity 280, configured to house an image sensor device in the desired position during testing. The device cavity 280 may include rounded cutouts comprising extended corners 285 to prevent the corners of the image sensor device from being chipped as the image sensor device is inserted and removed from the contactor 300. Cushioning, for example foam, may be provided within the device cavity 280. Optionally, a positioning part (not shown) may be placed over the seat 305 to aid in retaining the image sensor device in the desired position. The diffuser 290 has a lateral boundary 305′ larger than a lateral boundary 280′ of the device cavity 280. Referring back to FIG. 2B, the lateral dimensions of the diffuser 230 are lesser than the lateral dimensions of the device cavity 220. A diffuser of any size or shape is within the scope of the present invention. For example, the diffuser may be round, elliptical, or triangular.

The seat 305 may be molded from a polyamide-imide, or other suitable material. Optionally, the seat 305 may comprise an at least partially optically transparent material such as borosilicate glass (BSG), other types of glass, quartz or even a polymer of suitable material characteristics and which allow the passage of a desired range of wavelengths of light or other forms of electromagnetic radiation.

In a third embodiment of the present invention, depicted in FIGS. 4A and 4B, a single contactor 300 may include more than one device cavity 220, each device cavity 220 configured for receiving an image sensor device 210. Thus the contactor 300 may be used to test more than one image sensor device 210 simultaneously. The top view of the contactor 300 shows guide holes 221, enabling a cover to be properly aligned with the contactor 300 to provide electrical communication between the image sensor device 210 and the contactor 300.

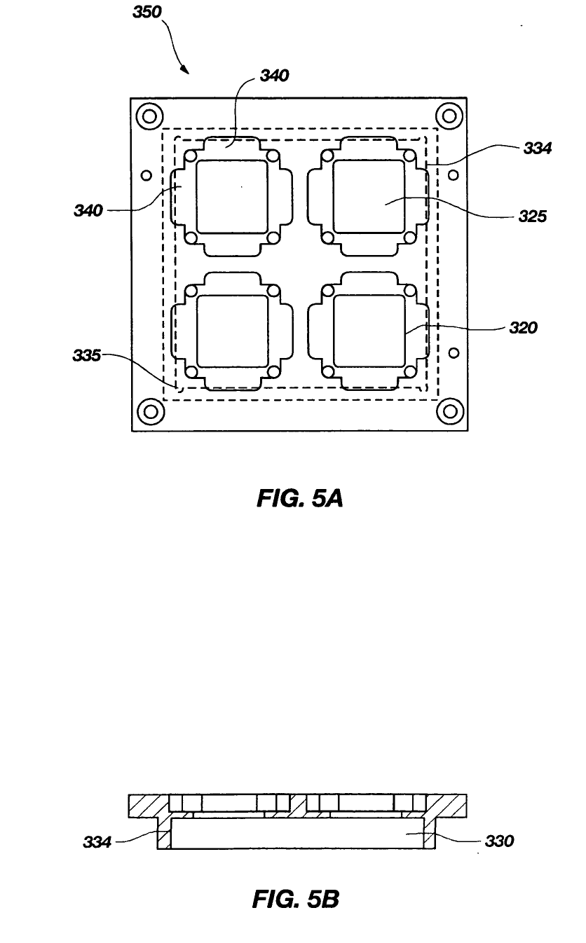

In a fourth embodiment of the present invention, depicted in FIGS. 5A-5B, a contactor 350 includes four device cavities 320 for receiving image sensor devices. Each device cavity 320 includes associated conductive pathways 260 (see FIG. 2B) configured for establishing electrical communication between an image sensor device and a carrier substrate or PCB 270 (see FIG. 2B). A diffuser 330 comprising a contiguous piece of material may be associated with the plurality of image sensor device cavities 320. Light may pass through the diffuser 330, and through each of the four apertures 325 to reach each associated image sensor device. Side pockets 340 providing clearance for the insertion and extraction of the image sensor device may be included. The diffuser 330 extends below each of the four image sensor device cavities 320. A diffuser cavity 334 within the contactor 350 may include chamfered corners 335 for facilitating the insertion of the diffuser 330. The diffuser may be affixed to the contactor 350, for example, using an adhesive or a retaining component.

In a fifth embodiment of the present invention illustrated in FIG. 6, an image sensor device 210 may be supported by a seat 420 of an at least partially optically clear material. The image sensor device 210 includes a housing 430 for effecting electrical connection to external circuitry. The housing 430 may provide such electrical connection in the form of discrete conductive elements 440, depicted in the form of solder conductive pins, leads, or lands. A cover (see FIG. 2) may be used to electrically connect the discrete conductive elements 440 with the contactor 450. A transparent lid 410 of the housing 430 allows light to pass through the housing 430 to an array of pixels 400 on image sensor device 210. The image sensor device 210 may be in the form of a shifted optic array, as shown, with the array of pixels 400 laterally offset from the center of the image sensor device 210. Receipt and testing of an image sensor device having a centrally located array of pixels 400 is additionally within the scope of the present invention. The depicted image sensor device 210 includes a first side 432, with the discrete conductive elements 440 positioned thereon, and a second, opposing side 434, including the transparent lid 410. The transparent lid 410 may be laterally offset from the center of the second side 434, as depicted, or may be centrally located. The array of pixels 400 is positioned adjacent the transparent lid 410, between the first side 432 and the second, opposing side 434 of the housing 430. The transparent lid 410 may comprise substantially the entire second side 434 of the housing 430, or the transparent lid 410 may have lateral dimensions substantially similar to those of the array of pixels 400.

The image sensor device 210 may be positioned within the socket, or contactor 450 on the seat 420. The seat 420 may be formed of an at least partially optically transparent material, enabling light 460 to pass therethrough. The at least partially optically clear material may be borosilicate glass (BSG), other types of glass, quartz or even a polymer of suitable material characteristics and which allow the passage of a desired range of wavelengths of light or other forms of electromagnetic radiation. The polymer allyl diglycol carbonate, sold under the trade name CR-39 by PPG industries of Pittsburg, Pa. may be suitable. A polymer may be machined to a specific desired size and shape, and may be more resistant than glass to particular types of damage, for example, damage from certain chemicals.

The light 460 is depicted as diffused light, incident upon the seat 420 at an angle. The light 460 strikes a first surface 423 of the seat 420 at a point 422 closer to the periphery 427 of the seat 420 than the point 424 on a second surface 425 at which the light exits the seat 420, striking the image sensor device 210. Thus it may be desirable to have a seat 420 having a lateral periphery 427 greater than the lateral periphery of the transparent lid 410, particularly when diffused light is used to test the image sensor device 210.

The seat 420, formed of at least partially optically clear material, enables light 460 to pass therethrough without requiring an aperture therethrough, for example the central aperture 306 of the seat 305 depicted in FIG. 3. It may be desirable when conducting testing of a plurality of image sensor devices to test each device at the same temperature. It may thus be desirable to maintain a constant temperature of the image sensor device 210 during testing. However, thermal control of the image sensor device may be difficult with a central aperture 306 positioned adjacent the image sensor device under test. Heat may escape through the central aperture 306. Therefore, a seat 420 having a contiguous surface 425 and no aperture may be advantageous.

Optionally, the seat 420 may comprise a diffuser. A polymer seat may have a matte finish, or be sandblasted to form a diffuser. Any suitable diffuser material, for example, ground glass, opal glass, or a holographic diffuser may be used to form the seat 420. The seat 420 is contiguous with the transparent lid 410 of the image sensor device 210, therefore most of the light scattered by the diffuser will reach the array of pixels 400.

Although the foregoing description contains many specifics, these should not be construed as limiting the scope of the present invention, but merely as providing illustrations of some exemplary embodiments. Similarly, other embodiments of the invention may be devised that do not depart from the spirit or scope of the present invention. Features from different embodiments may be employed in combination. The scope of the invention is, therefore, indicated and limited only by the appended claims and their legal equivalents, rather than by the foregoing description. All additions, deletions, and modifications to the invention, as disclosed herein, which fall within the meaning and scope of the claims, are to be embraced thereby.

What is claimed is:

1. A contactor for use in testing an optically interactive electronic device, comprising:
a device area configured for receiving the optically interactive electronic device, wherein the optically interactive electronic device may be removably mounted on the device area;
an optic port extending through the contactor to enable light to reach the device area; and
a diffuser positioned proximate to the device area across an intended path of the light.

2. The contactor of claim 1, wherein the device area comprises a cavity within the contactor for receiving the optically interactive electronic device.

3. The contactor of claim 1, wherein the diffuser is positioned within the optic port.

4. The contactor of claim 1, wherein the diffuser comprises one of etched glass, silica substrate, ground glass, opal glass, and polycarbonate.

5. The contactor of claim 1, wherein the diffuser is configured to provide support for the optically interactive electronic device.

6. The contactor of claim 1, further comprising a seat of at least partially optically clear material configured to provide support for the optically interactive electronic device.

7. The contactor of claim 6, wherein the at least partially optically clear material comprises at least one of borosilicate glass, glass, quartz, a polymer, and CR-39.

8. The contactor of claim 1, further comprising at least another device area configured for receiving at least another optically interactive electronic device.

9. The contactor of claim 8, wherein the diffuser comprises two discrete diffusers, each discrete diffuser positioned proximate to a device area.

10. The contactor of claim 8, wherein the diffuser comprises a contiguous diffuser, extending proximate to the device area and the at least another device area.

11. The contactor of claim 1, further comprising at least another three device areas configured for respectively receiving at least another three optically interactive electronic devices.

12. The contactor of claim 11, wherein the diffuser comprises four discrete diffusers, each discrete diffuser positioned proximate to a device area.

13. The contactor of claim 11, wherein the diffuser comprises a contiguous diffuser, extending proximate to each of the at least another three device areas.

14. The contactor of claim 1, wherein the optically interactive electronic device comprises an image sensor device.

15. The contactor of claim 1, wherein the diffuser is positioned between 0.1 to 1.0 millimeters from the device area.

16. The contactor of claim 1, wherein the diffuser is positioned between 0.3 to 0.5 millimeters from the device area.

17. A system for testing an optically interactive electronic device, comprising:
a carrier substrate;
a test socket operatively connected to the carrier substrate and configured to removably receive the optically interactive electronic device; and
a diffuser for diffusing light incident on the optically interactive electronic device received by the test socket.

18. The system of claim 17, wherein the diffuser is located proximate to the carrier substrate.

19. The system of claim 17, wherein the diffuser is located within the test socket.

20. The system of claim 19, wherein the diffuser is located between 0.1 to 1.0 millimeters from the device area.

21. The system of claim 19, wherein the diffuser is located between 0.3 to 0.5 millimeters from the device area.

22. The system of claim 19, wherein the diffuser is configured to provide support for the optically interactive electronic device received by the test socket.

23. The system of claim 17, further comprising an at least partially optically clear seat located within the test socket for supporting the optically interactive electronic device.

24. The system of claim 23, wherein the at least partially optically clear seat comprises at least one of borosilicate glass, glass, quartz, a polymer, and CR-39.

25. The system of claim 23, wherein the at least partially optically clear seat includes an aperture therethrough.

26. The system of claim 23, wherein the at least partially optically clear seat comprises a contiguous piece of at least partially optically clear material.

27. The system of claim 17, further comprising a light source for producing the light incident on the optically interactive electronic device.

28. The system of claim 27, wherein the light source is configured to produce collimated light.

29. The system of claim 17, wherein the optically interactive electronic device comprises an image sensor device.

30. A method of testing an optically interactive electronic device, comprising:
projecting light through a diffuser;
receiving the projected light with the optically interactive electronic device;
recording an electrical image of the projected light with the optically interactive electronic device; and
communicating the electrical image to a processing device for evaluation of the optically interactive electronic device.

31. The method of claim 30, wherein projecting light comprises:
providing a light source emitting collimated light;
projecting the collimated light through an optical port of a printed circuit board; and
diffusing the collimated light.

32. The method of claim 30, wherein projecting light comprises:
providing a light source emitting collimated light;
diffusing the collimated light; and
projecting the diffused light through an optical port of a printed circuit board.

33. The method of claim 30, wherein projecting light comprises projecting light through a diffuser located between 0.1 to 1.0 millimeters from the optically interactive electronic device.

34. The method of claim 30, wherein projecting light comprises projecting light through a diffuser located between 0.3 to 0.5 millimeters from the optically interactive electronic device.

35. The method of claim 30, further comprising supporting the optically interactive electronic device with a test socket, wherein the diffuser is located within the test socket.

36. The method of claim 30, further comprising supporting the optically interactive electronic device with the diffuser.

37. The method of claim 30, further comprising supporting the optically interactive electronic device with a seat formed of an at least partially optically clear material.

38. The method of claim 30, further comprising receiving the projected light with a plurality of optically interactive electronic devices.

39. The method of claim 30, wherein the optically interactive electronic device comprises an image sensor device.

40. A method of testing an optically interactive electronic device, comprising:
supporting the optically interactive electronic device with a socket including a support structure formed of an at least partially optically clear material;
connecting the socket with a carrier substrate;
projecting light through the carrier substrate;
receiving the projected light with the optically interactive electronic device;
recording an electrical image of the projected light with the optically interactive electronic device; and
communicating the electrical image to the carrier substrate.

41. The method of claim 40, wherein supporting the optically interactive electronic device comprises supporting the optically interactive electronic device on a surface of the support structure contiguous with a window of the optically interactive electronic device.

42. The method of claim 40, further comprising diffusing the projected light prior to projecting the light through the carrier substrate.

43. The method of claim 40, further comprising diffusing the projected light after projecting the light through the carrier substrate.

44. The method of claim 40, wherein the optically interactive electronic device comprises an image sensor device.

45. A socket for testing an optically interactive electronic device, comprising:
a device area for removably mounting the optically interactive electronic device;
an optic port extending through the socket to enable light to reach the device area; and
a seat positioned in the optic port comprising an at least partially optically clear material and having a support surface configured to abut an optically interactive electronic device mounted in the device area.

46. The socket of claim 45, wherein the device area comprises a cavity within the socket for receiving the optically interactive electronic device.

47. The socket of claim 45, wherein the seat comprises a diffuser.

48. The socket of claim 47, wherein the diffuser comprises one of etched glass, silica substrate, ground glass, opal glass, and polycarbonate.

49. The socket of claim 45, wherein the at least partially optically clear material comprises at least one of borosilicate glass, glass, quartz, a polymer, and CR-39.

50. The socket of claim 45, further comprising another device area configured for receiving another optically interactive electronic device.

51. The socket of claim 45, wherein the optically interactive electronic device comprises an image sensor device.
